(19) United States
(12) Patent Application Publication
(10) Pub. No.: US 2025/0307537 A1
(43) Pub. Date: Oct. 2, 2025

(54) AUTOMATED GENERATIVE AI BASED DIGITAL TWIN

(71) Applicant: Intel Corporation, Santa Clara, CA (US)

(72) Inventors: Rafael Rosales, Unterhaching (DE); Dave A. Cavalcanti, Portland, OR (US); Vesh Raj Sharma Banjade, Portland, OR (US); Susruth Sudhakaran, Beaverton, OR (US)

(21) Appl. No.: 18/617,942

(22) Filed: Mar. 27, 2024

(51) Int. Cl. G06F 40/20

(52) U.S. Cl. CPC G06F 40/20

(57) ABSTRACT

A system for creating a digital twin of a system under test may comprise processing circuitry and memory, with instructions stored thereon which, when performed by the processing circuitry cause the processing circuitry to receive multiple inputs with information corresponding to the system-under-test and provide the multiple inputs as a data input to a large language model. The processing circuitry may further configure an experiment with the large language model based on the multiple inputs, configure a process flow for the experiment, using data output generated from the large language model, and generate a training data set using the experiment and the process flow. The training data set may be used by the processing circuitry to create or configure the digital twin.

### BACKGROUND

A system under test (SUT) refers to a system being tested or evaluated for correct operation. An SUT is often used when testing software or modeling real-world systems such as robotics or fabrics. A digital twin, which provides a model of the SUT (e.g., a platform or product) created in a virtual environment. The digital twin can be used to experiment and validate performance using for example, real-world data. A digital twin can be used to predict hypothetical scenarios of the system in real-time.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1A illustrates an example flow diagram for training a digital twin of a system under test.

FIG. 1B illustrates an example process to obtain training data to create a digital twin.

FIG. 2 illustrates an example of configuring an experiment and process flow using a Large Language Model.

FIG. 3 illustrates pre-processing of an experiment instruction to augment sampling prompts using an explicit heuristic.

FIGS. 4A and 4B illustrate example flow diagrams for capture of input and output features of a sample.

FIG. 5 illustrates a method creating or configuring a digital twin of a system under test.

FIG. 6 is a block diagram of an example of a machine that can be used to help perform one or more of the techniques (e.g., methodologies) discussed herein.

### DETAILED DESCRIPTION

A digital twin is a model of the behavior (of interest) of a system under test (SUT). The SUT may include, for example, a real-world object, device, or system such as a robot, a factory, software, or a network. Digital twins may be created programmatically or data-based, such as with a Deep Neural Network (DNN). In some examples a designer must manually prepare the process to extract all training data necessary for the digital twin, (e.g., write the code to make Application Programming Interface (API) call flows of the system, record the system behavior, or the like). The present disclosure discusses systems and methods to automate the creation process of training data to model a digital twin that mimics the SUT. The systems and methods discussed herein may utilize the capabilities of Large Language Models (LLMs) to understand the APIs and translate human-level specification of experiments to obtain samples of training data.

Some example methods used to collect training data include manual training, crowdsourced training (to obtain large datasets), and data augmentation (to increase the number of samples for training from an existing set by applying a set of transformations to the known samples). Other techniques for obtaining training data may include automated data collection techniques such as web scraping or the use of APIs (services or simulators), or knowledge distillation (KD). KD is a technique that enables training an artificial intelligence (AI) model using another AI model as a teacher by providing new target samples (e.g., more detailed expected outputs). Use of manual and crowdsourced approaches may be difficult to guarantee the quality and consistency of the obtained samples. Data augmentation may not be suitable to obtain rare samples that belong to a tail of a distribution. Automated data collection enables access to data for training but is typically not unsupervised and may not be suitable for high-quality annotated data, and KD does not produce new input samples.

Other techniques used for data sampling may include random sampling which may produce aleatory sample points, cluster sampling in which sampling space may be divided to ensure more balanced sample, or Markov Chain Monte Carlo (MCMC) to increase the efficiency of obtaining samples from a probability distribution and enable capture samples of a rare occurrence. Random sampling may be too inefficient to obtain a small set of meaningful samples and cluster sampling cannot guide the sampling process to all cases of interest. MCMC may be difficult to obtain convergence and requires human expertise, and the samples are typically correlated.

Some techniques that attempt to integrate APIs into a Large Language Model may include use of rules to provide a description of the functionality of the models (e.g., using model cards), human instructions (self-instruct) to create a dataset of human-language instructions from a smaller available set to create specific instances of the instructions that include generated inputs and outputs. Other techniques may include retrieving a set of API calls with overlapping functionality from a database, or using a language model that learns to use an API from examples by annotating the dataset with potential API calls and then with a self-supervised loss to determine whether a tool helps to predict the next token. Model cards provide a description at mostly a human level, self-instruct samples are populated (and limited) according to the internal knowledge of the language model, and tools can learn to use the API but cannot develop a strategy to obtain samples from the API, and they require retraining.

To enable different kind of experiments that may require multiple API calls, with a specific order or timing, a set of rules to be compliant within a human-level specification of the experiments may be defined and used. Further, a set of atomic actions, and a dependency graph (which may be annotated with the final training data to make the data origin understandable) may be used to specify flows as imperative procedures, as well as parallel synchronous and asynchronous events. The LLM may be requested to generate a text description of the interpreted actions and dependency graph, enable formal analysis before execution, or the like.

A system for creating or configuring a digital twin of a system under test may automate extraction of the training data using generative AI, which can help overcome some of the technical challenges discussed above. The system may receive multiple inputs with information corresponding to the SUT. The multiple inputs may be provided as a data input into a Large Language Model (LLM). The LLM may configure an experiment based on the multiple inputs and the system may configure a process flow for the experiment using data output generated from the large language model. The system may generate a training data set using the experiment and the process flow and configure a digital twin of the SUT using the training data set. An input may include a natural language description of the experiment. A second input may include application programming interface documentation of the SUT. When configuring the experiment, the system may use the natural language description of the experiment to generate a plurality of augmented experiments (e.g., variations or permutations of the experiment) in real-time, which may then be run by the digital twin to test the different variations.

The present disclosure overcomes the limitations discussed above by applying a Large Language Model to understand the API of a system under test and a description of experiments that need to be performed to enable an automated extraction of training samples to create or configure a digital twin of the system under test. The experiment of interest (and the variations) and the process flow may be determined in real-time according to a predefined set of rules indicating what actions to perform, the order in which the actions should be performed, and what outputs will be relevant. Furthermore, the experiments and process flow may be configured by the LLM and then used to generate the training data set using the experiments and the process flows generated by the LLM at the same time (or substantially the same time), which involves processing much more data than a human can do at one time, and then create or configure the digital twin based on the training data set.

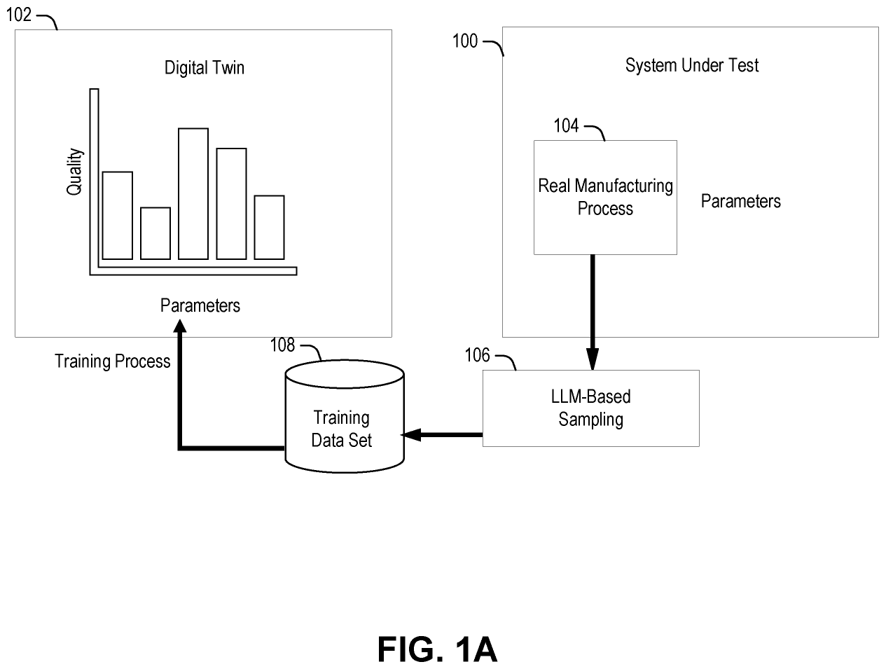

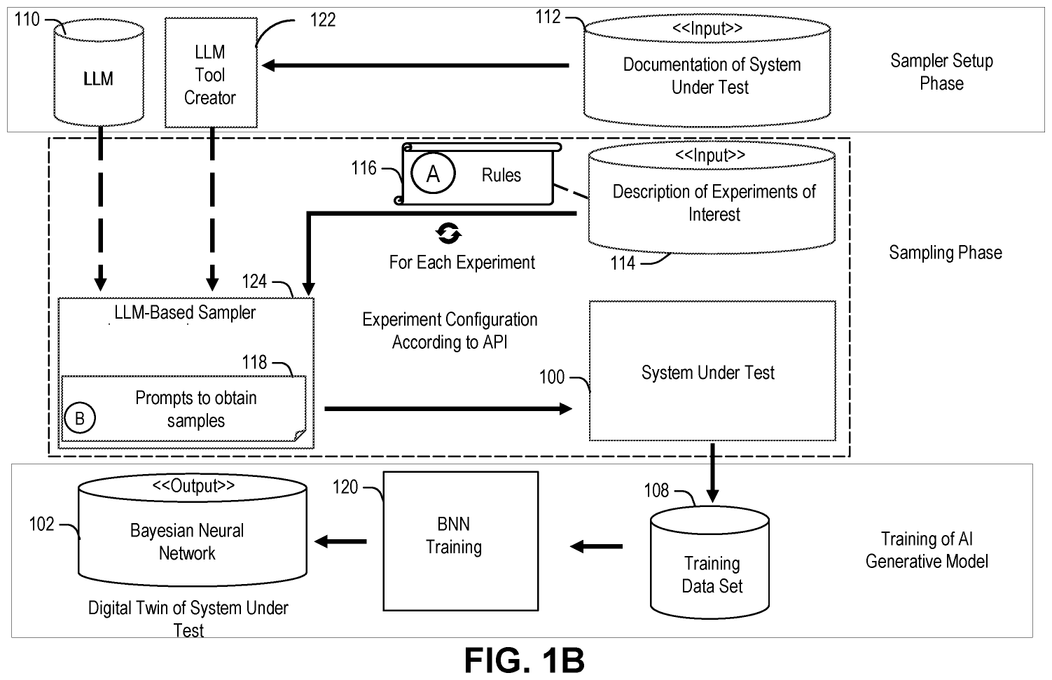

FIG. 1A illustrates an example flow diagram for training a digital twin of a system under test. A system under test (SUT 100) may be any system that is being tested for correct operation such as a software-system, a manufacturing process, or the like. In the example of a manufacturing system, the SUT 100 may include a manufacturing process 104. Data obtained during the manufacturing process 104 may be input into a Large Language Model (LLM) to obtain an LLM-based sampling 106, which may include an input-output pairing discussed below, which may be used as a training samples (training data set 108). The training data set 108 may be used to create or configure (e.g., train) a digital twin 102 of the SUT 100.

FIG. 1B illustrates an example process to obtain training data to create a digital twin. As illustrated in FIG. 1B, inputs into a Large Language Model (LLM 110) or a LLM tool creator 122, may include documentation specific to the system under test (SUT documentation 112) and a description of the experiment of interest (experiment description 114). In an example, the SUT documentation 112 may include documents such as operating instructions, specifications, quick-start guides, or the like, specific to the operation of the SUT 100. The experiment description 114 may include a description of the experiment to be run. The description may include a natural language description of how the test should be performed. The experiment description 114 may include a set of rules 116. The rules 116 may define a) the explicit identification of the input and outputs of the sample, b) a general but constrained control flow specification in human language to enable the operation of processes (sequential or not-sequential), and c) the format of the action primitives to call steps using arguments and how to store the results. The rules 116 may be used to create a set of instructions, instructing on or more action primitives or action items corresponding to or related to the SUT documentation 112. For example, a documented function of the system may be “read temperature” in the SUT documentation 112. In such an example, the rules 116 may specify that any natural language description in the experiment description 114 about reading or measuring temperature will result in an action to measure the temperature. Thus, the LLM 110 may, using a sampler 124, prompt the SUT 100 to obtain samples based on the inputs by sending one or more prompts 118 to the SUT 100 (e.g., calls to the API of the SUT 100). The training data set 108 may be created based on the one or more prompts 118 and sent to a trained learning model (BNN 120). In an example, the BNN 120 may be a Large Language Model, and may be the same Large Language Model, LLM 110 (e.g., the training data set may be fed back to the LLM 110) or may be a different Large Language Model. The BNN 120 may be used to create or configure the digital twin 102.

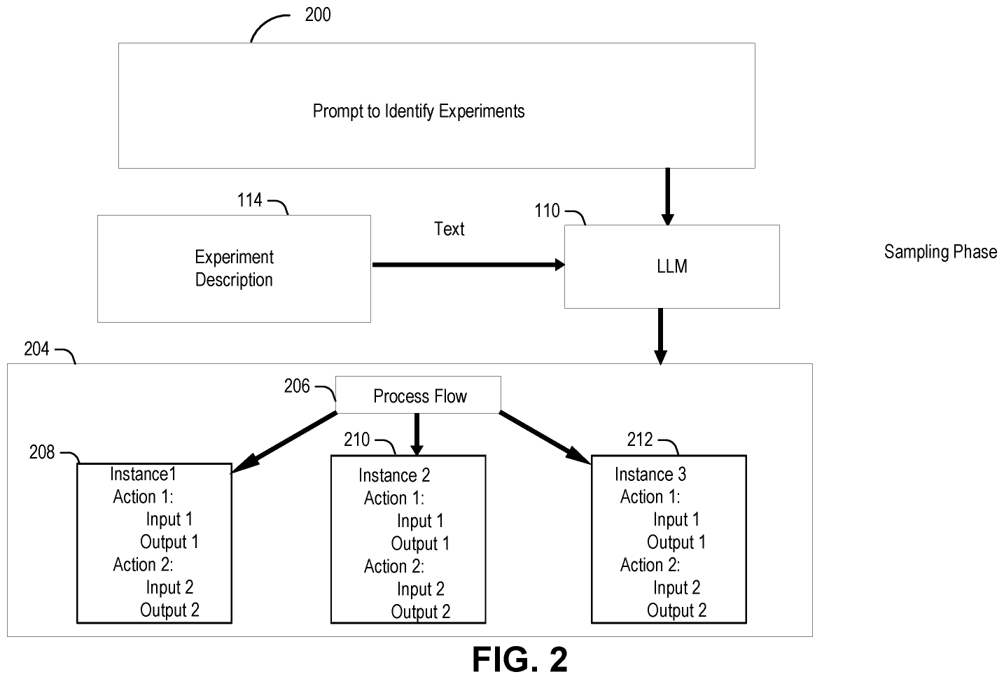

FIG. 2 illustrates an example of configuring an experiment and process flow using the Large Language Model. As discussed above in FIG. 1B, inputs into the LLM 110 include the experiment description 114 and SUT documentation 112. An input may also include an experiment identification prompt 200. The experiment identification prompt 200 may include a set of instructions to the LLM 110 to extract actions or operations based on the text of the experiment description 114 to identify a process flow 206 for the experiment. For example, the experiment identification prompt 200 may include instructions to identify actions in the text of the experiment description 114 and provide each action with an identifier and create a list of the identifiers. The instructions may also instruct the LLM 110 to indicate a list of the inputs and outputs for the experiment description 114 and/or to provide a graph representation of the process, indicate any dependencies or timing of actions in the process (e.g., indicate that a first action “ID1” must precede a second action “ID2”, and so on. Configuring the experiment may include using the natural language description of the experiment to generate a plurality of augmented experiments (Instance-1 208, Instance-2 210, and Instance-3 212), which may be different variations or permutations of the process flow 206. For an experiment entered into the LLM 110 as a natural language description may include “to manufacture a drink, first make a bottle of glass using 100 mg of sand. The temperature must be 200 centigrade and the time of the heating should be 2 minutes. Second, mix the content. The content is composed of 0.5 liters of water plus 10 mg of syrup. Third, fill the bottle with the content. Fourth, close the bottle using the cap. Based on this description, the LLM 110 may describe and graph a process flow 206 as:
MANUFACTURE_BOTTLE->MIX_CONTENT->FILL_BOTTLE->CLOSE_BOTTLE.

In such an example, the identified actions in the process are 1) Manufacturing the bottle; 2) Mixing the Content; 3) Filling the Bottle; and 4) Closing the Bottle. For each action, the system may determine, or the rules may require different iterations. In each iteration, inputs for each action may vary. For example, in the Manufacturing the Bottle action, the inputs for the first iteration may include 100 mg of sand, heating at a temperature of 200 centigrade, and heating for two minutes. In the second iteration, the inputs for the action may include 110 mg of sand, heating at a temperature of 220 centigrade for 1.8 minutes. In the third iteration, the inputs for the action may include 90 mg of sand, heating at 180 centigrade for 2.2. minutes. Similarly, in each iteration, the action of mixing the content may vary (e.g., the amount of water and syrup to be mixed may vary in each iteration). Thus, the LLM 110 may create an interpretable API call flow that unambiguously specifies the set of actions, the order and timing of execution of the actions, or the like. In an example, the training data may be annotated for debugging and analysis.

An action a is defined as an operation c that can be carried away by a single command, which receives a set of inputs I and produces a set of outputs O:

$$a = \{ c , I , O \} \qquad Equation 1$$

An action may be specified in natural language whenever the three members are well defined. For example, a natural language description of “Compute the first 3 prime numbers” may be mapped to: C: list<int> prime_numbers(int start, int end), I: 1, O: 3.

In another example, the experiment identification prompt 200 may include an instruction to identify actions together with the inputs and outputs. In the example of manufacturing the drink, for the Manufacturing the Bottle action, the inputs may include 100 mg of sand heated to 200 centigrade for 2 minutes, and the output may be a bottle of glass. For the content mixing action, the inputs may be 0.5 liters of water and 10 mg of syrup, and the output may be a mixture of water and syrup. For the filling the bottle action, the inputs may be the bottle of water and glass and the mixture of the water and syrup, and the output may be a bottle filled with mixture. Finally, for the closing action, the inputs may be the bottle of glass filled with the mixture and a bottle cap, and the output may be a sealed bottle.

An experiment may be defined as a dependency graph of atomic actions, enabling the execution of sequential or parallel actions to obtain a result. A dependency graph G may be constructed by directed edges e that interconnect action nodes A, given by:

$$e = \{ {a}_{src} , {a}_{dst} \} \qquad Equation 2$$

$$G = \{ A , E \} \qquad Equation 3$$

An edge may indicate a precedence requirement of one action to another. The dataflow of the executed actions may be specified through dataflow edges d, that indicate a mapping of a particular output oₘ of an action to an input iₙ of another given by:

$$d = \{ {a}_{src} \cdot {o}_{m} , {a}_{dst} \cdot {i}_{n} \} \qquad Equation 4$$

Furthermore, an action may indicate to store or read the value of an output with a a_{write} or a_{read} respectively. A dependency graph may be specified in natural language as a set of sentences that describe the partial order constraints between actions, as well as the mapping of output to inputs for the dataflow. For example, as shown in Table 1 below, a natural language description of “first read the temperature and then compare the reading to the annual average” may be mapped a set of actions.

TABLE 1
Dependency Graph Mapping

| Natural language | “First read the temperature and then compare |
|---|---|
| description of an action: | the reading to the annual average” |
| Mapped to: | a₁ = {C_{read}, Ø, temp} |
| | a₂ = {c_{compare}, i, result} |
| | e₁ = {a₁, a₂} |
| | d₁ = {a₁.temp, a₂.i} |
| | G = {{a₁, a₂}, e₁} |

The dependency graph may be annotated with a partial order tag t to each action. In this way, a deterministic execution of otherwise independent actions may be made. Thus, Eqn. 1 may be modified as:

$$a = \{ c , I , O , T \} \qquad Equation 5$$

Where T is a set of tags. Additionally, the tag may indicate a specific timestamp, as to schedule an execution at a particular time. It is understood that the partial order and timestamp are not exclusive annotations. A discrete event simulation may enable delta iterations within a single timestamp.

In another example, basic control flow actions, such as “IF,” “WHILE,” “FOR,” “CASE,” are interpreted directly by the LLM to generate the appropriate dependency graph that introduces COMPARISON actions a_{compare} (with a pre-defined functionality to branch), to enable the branching action to implement these actions. For example, a natural language description “if the water level is low, turn the pump on” may be mapped as shown in Table 2.

TABLE 2
Control Flow Mapping

| Natural language | “If the water level is low, |
|---|---|
| description of an action: | turn the pump on” |
| Mapped to: | a_{compare} = {c_{compare}, i_{water}_{_{—}}ₗₑᵥₑₗ, Ø} |
| | eₜᵣᵤₑ = {a_{compare}, aₚᵤₘₚ} |
| | e_{false} = {a_{compare}, Ø} |

Thus, given a dependency graph generated by the LLM from the description of experiments, another LLM instance may translate it to a flow of API calls according to the provided documentation, specifications, or the like. The creation of the prompts to obtain the training samples can be a 1:1 map of the dependency graph, or it may be augmented through a set of heuristics to augment the generated data in a systematic way.

The augmentation of sampling prompts can be specified using different approaches. A first approach may be experiment specific. In such an approach, the experiment may define the desired augmentation techniques as a part of the experiment definition. For example, the augmentation can be embodied by a statement of a desired number of executions to gather variations and/or specifying randomness in the graph.

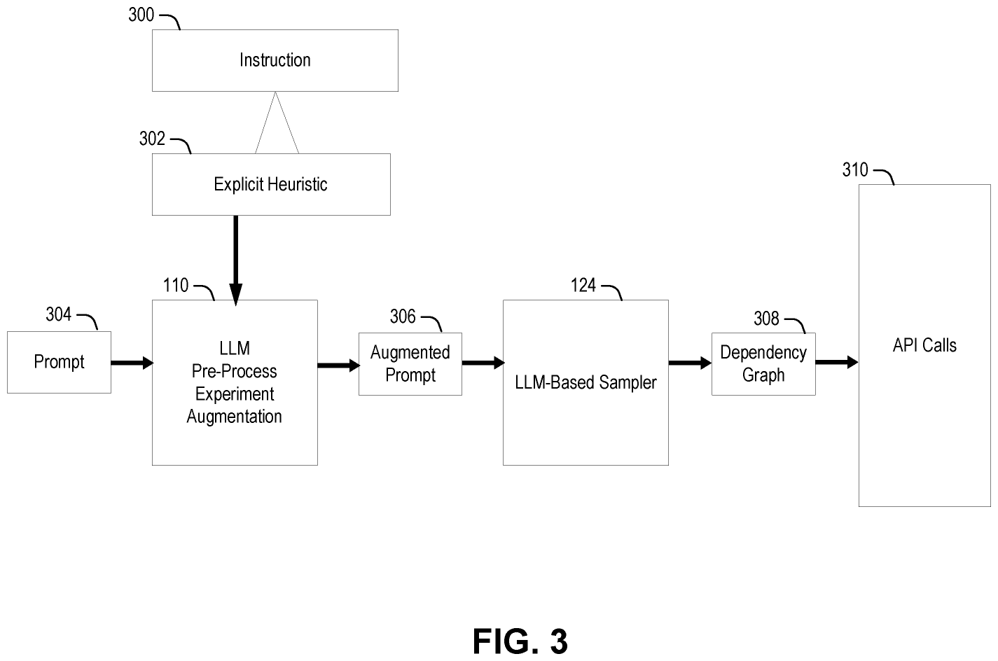

Another approach may include the use of explicit heuristics. In such an approach, a set of prompt rules or instructions may be provided that pre-process the original textual experiment description to insert variations according to the instructions. FIG. 3 illustrates pre-processing of an experiment instruction to augment sampling prompts using an explicit heuristic.

As illustrated in FIG. 3, a set of instructions 300 may include an explicit heuristic 302 (e.g., prompt instructions) that may be pre-processed by the LLM 110. The pre-processing may be performed at the same time, or substantially the same time as a prompt 304 (e.g., the natural language description of the experiment) is sent, transmitted to, or the like, the LLM 110. In such an example, the LLM 110 may pre-process the original textual description to insert one or more variations according to the supplied rules (e.g., rules 116). For example, the set of instructions 300 may include an instruction to take photos from different perspectives and the prompt 304 may indicate that if the camera is allowed to be moved, it should be moved to different positions each time that a photo must be taken. When the experiment is pre-processed, the LLM 110 may produce or generate an augmented prompt 306 with one or more new instances that explicitly add actions and send the new instances to the LLM-based sampler 124. For example, the new instances may include take a picture, move the camera to a minimum range, then take a picture, move the camera to a half-range, then take a picture, move the camera to a maximum range, then take a picture, etc. Thus, the LLM-based sampler 124 may generate a dependency graph 308 indicating a sequence in which the pictures at the given distances/ranges are to be taken, and the LLM-based sampler 124 may then initiate API calls 310 to generate the samples to be used as training data.

Another approach is to use implicit heuristics to augment the sampling prompts. In such an approach, a meta-prompt may be specified to leverage the knowledge of the LLM to pre-process the experiment description and introduce diversity in the experiment. As such, when the experiment description is entered or transmitted to the LLM, the LLM may automatically, using trained-learning techniques (e.g., artificial intelligence or machine-learning models or algorithms) to determine different variations of the experiment.

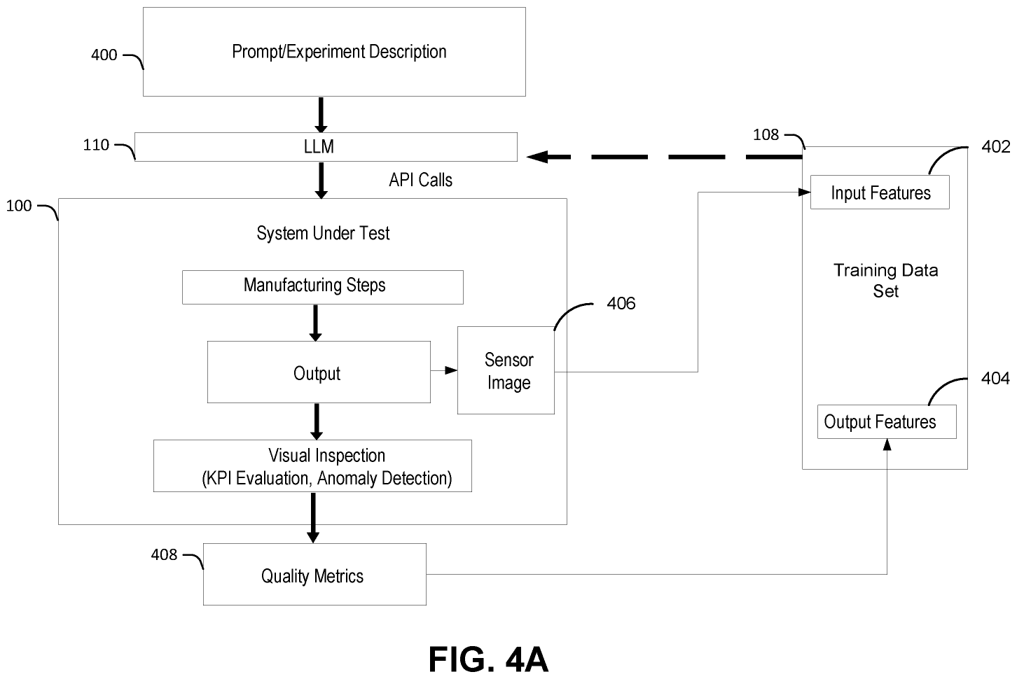

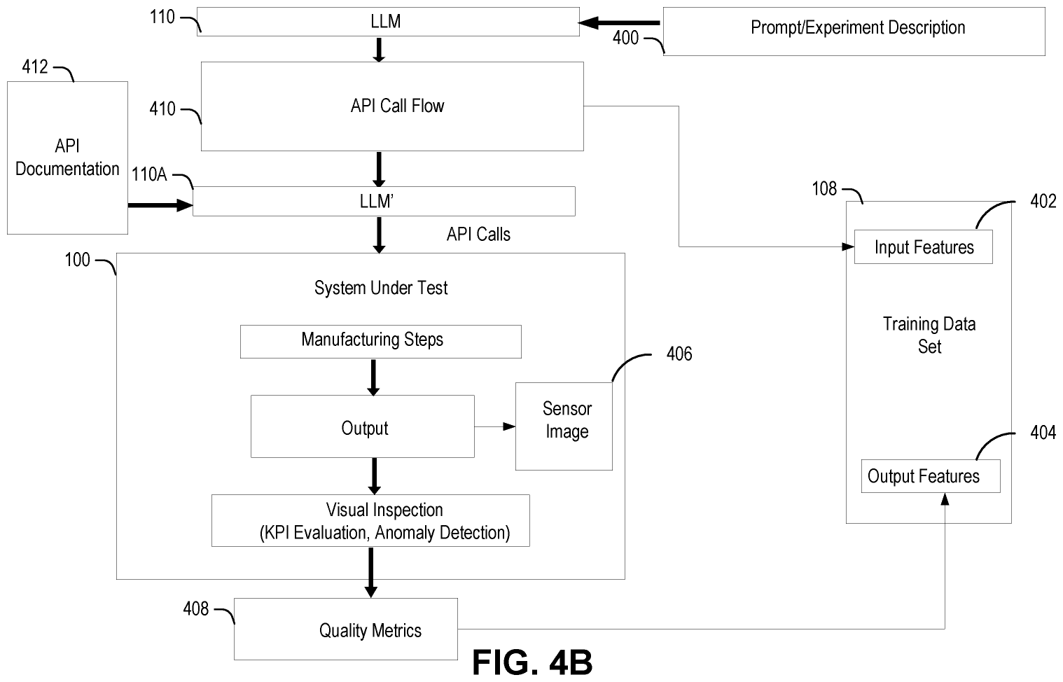

FIGS. 4A and 4B illustrate example flow diagrams for capture of input and output features of a sample. The creation of sampling data may be initiated by a command from the user. As shown in FIG. 2, the command can include a prompt and a separate experiment description entered into the LLM 110. In another example, the experiment description may be included or embedded in the prompt. For example, the prompt may include a template and the experiment may be entered as a variable in the template. Thus, the command may be a single command that instructs the sampler to iterate through all experiments according to a set of generated prompts that ensure the experiments run as expected (e.g., as indicated by the rules following dependencies, using correct arguments, according to a policy, or the like). The LLM 110 may issue one or more API calls to the SUT 100 to generate a sample. The sample may contain a pair of input features 402 and output features 404 (e.g., a target output) which may be stored as the training data set 108. The input and output features may be explicitly specified in the experiment description 400 passed to the LLM 110, thus any parameter of interest may be used. In an example, the training data set 108 may be created using any initial parameters, or with images, such as sensor image 406, as an input feature captured with an imaging sensor (e.g., a camera) during execution of the SUT 100. In an example, the output features 404 may be created using a one or more quality metrics 408 generated by the SUT 100 in response to the API calls from the LLM 110. The experiment description 400 may be performed during inference in real-time (or near real-time) as the process to create new samples may be automated from a human language description. The generative model (the LLM 110) may then be fine-tuned with the training data set 108 (as denoted by the dashed arrow from the training data set 108 to the LLM 110).

In the example illustrated in FIG. 4B, the experiment description 400 may be input into the LLM 110, which, in turn, may generate an API call flow 410. Information or data generated from the API call flow 410 and API documentation 412 may be used as an input to LLM′ 110A, which may be the same LLM or a different LLM as LLM 110. In an example, a tool creator may be used to wrap, convert, or the like, the API documentation 412 to a format than an inference algorithm can understand or interpret. From there, API call flows may be sent to the SUT 100 to generate the output features 404.

In another an example, information or data generated in the API call flow 410 may be used as the input features 402 in the training data set 108. In such an example, the captured features to be used as the inputs may be specified separately so that intermediate results, such as the sensor image 406 may be used to generate a set of pictures. The experiments by the SUT 100 should define enough details to obtain final key performance indicators (KPIs) that may be used to generate the one or more quality metrics 408 to serve as the output features 404 in the training data set 108 for each training data set sample.

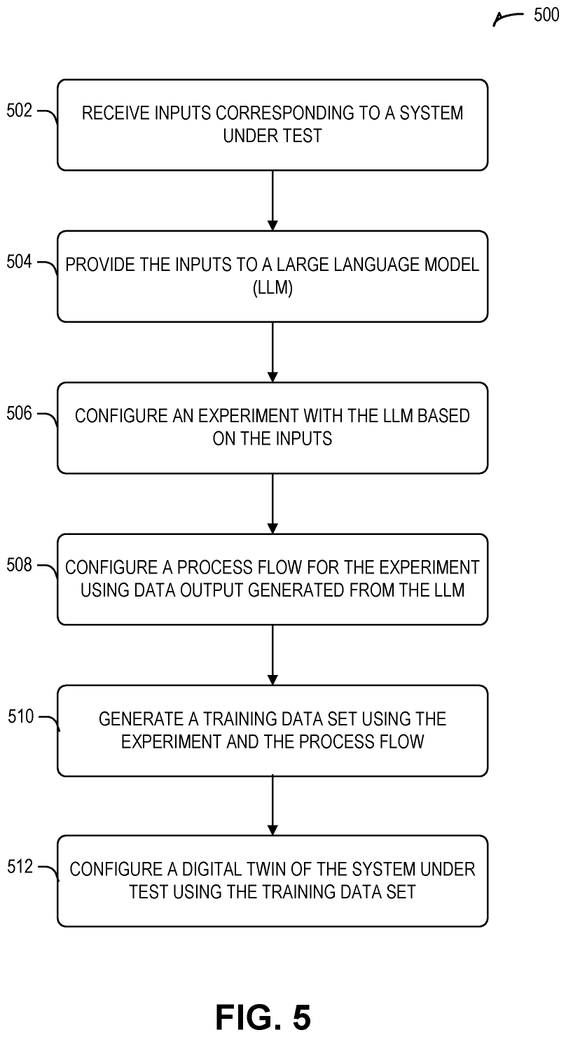

FIG. 5 illustrates a method creating or configuring a digital twin of a system under test (SUT). The method 500 can include or comprise a number of Operations. The Operations described herein are examples only, and the method can omit one or more of the listed Operations, can repeat Operations, can include other Operations, or can execute the Operations concurrently, substantially simultaneously, or in another order, as appropriate or desired.

Operation 502 may include receiving an input with information corresponding to the SUT. In an example, the input may be a single prompt including an embedded description (e.g., a natural language description) of an experiment to be performed to obtain a training data set. In another example, the input may include multiple inputs. In such an example, a first input may include a natural language description of the experiment. A second input may include application programming interface (API) documentation, documentation corresponding to the operation of the SUT, or the like. A third input may include one or more rules defining an input and an output for one or more actions used to configure the experiment.

Operation 504 may include providing the input to a Large Language Model (LLM). The LLM may be any trained model with the ability to achieve general-purpose language generation, natural language processing, classification, or the like. Operation 506 may include configuring an experiment with the LLM based on the inputs. Configuring the experiment may include using a natural language description of the experiment (e.g., as an input to the LLM) to generate one or more actions or sub-actions to be performed to conduct the experiment. Configuring the experiment may further include generating a plurality of augmented experiments in real-time (e.g., at the same time or substantially the same time as the experiment is configured). The plurality of augmented experience being permutations or variations of the experiment and determined from the natural language description of the experiment and a description of two or more modifications to be made to the experiment.

Operation 508 may include configuring a process flow for the experiment using data output generated from the LLM. The process flow may include a series of end-to-end actions required to perform the experiment. The actions generated in Operation 506 may be sub-actions in each instance of the experiment, and each of the sub-actions may include one or more inputs and one or more outputs. Configuring the process flow may include constructing or generating a dependency graph of the actions and sub-actions. The dependency graph may show the order in which the actions or sub-actions should be performed during each instance of the experiment. The dependency graph may be used to create a log that documents the one or more actions to be taken to perform the experiment. The dependency graph may be stored in a database that can be accessed by a user or by another trained learning model to improve the experiment definitions. The dependency graph may be annotated with an order tag (or a partial order tag). The order tag may include a timestamp setting for the timing of the actions or sub-actions or a delta cycle for the one or more actions. In an example, when the SUT is a simulator, there may be actions that are executed at the same timestamp but still need an order for their execution. The delta cycle may be used to define the order of the actions to be executed at a single timestamp. Thus, the tag may define a virtual order for the actions so that actions that may be performed concurrently or at the same time, are performed in sequence in the digital twin representation of the SUT.

Operation 510 may include generating a training data set using the experiment and the process flow. The training data set may be generated by a command that causes a processor to iterate through the plurality of augmented experiments using a set of generated prompts. The training data set may include a stored input feature and a stored output feature which, at Operation 512 may be used to create, configure, or train a digital twin of the SUT. The training data set may be feed back into the LLM to further train the LLM.

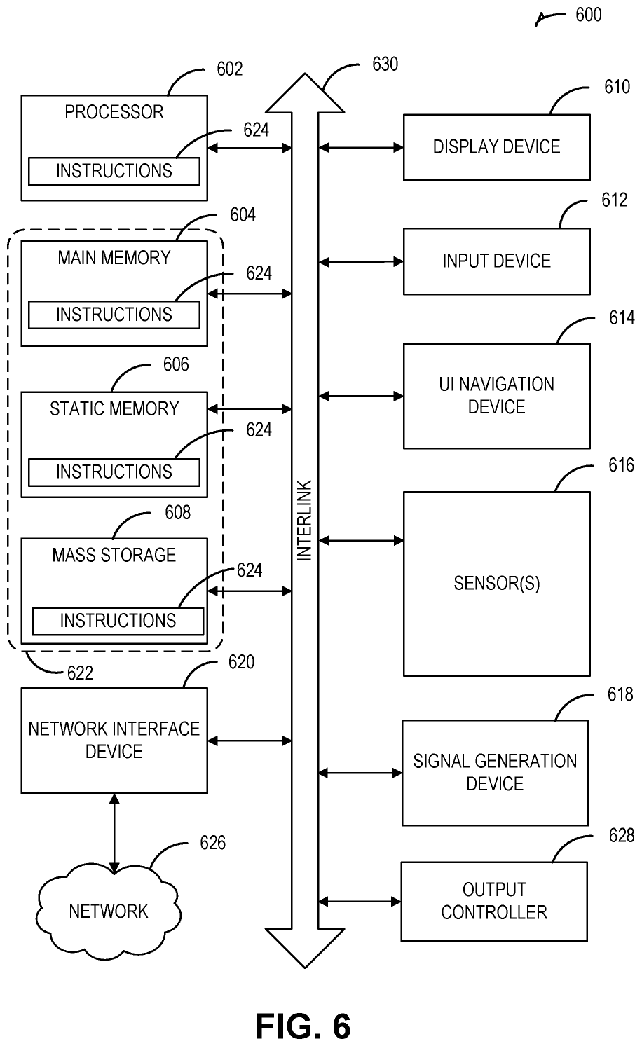

FIG. 6 is a block diagram of an example of a machine 600 that can be used to help perform one or more of the techniques (e.g., methodologies) discussed herein. The machine 600 can operate as a standalone device or can be connected (e.g., networked) to other machines. The machine 600 can operate one or more of the algorithms discussed above or include the LLM discussed in FIGS. 1A-4B. In a networked deployment, the machine 600 can operate in the capacity of a server machine, a client machine, or both in server-client network environments. In an example, the machine 600 can act as a peer machine in peer-to-peer (P2P) (or other distributed) network environment. The machine 600 can be a personal computer (PC), a tablet PC, a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” can include any collection of machines that individually or jointly execute a set (or multiple sets) of instructions to perform any one or more of the methodologies discussed herein, such as cloud computing, software as a service (SaaS), other computer cluster configurations.

Examples, as described herein, can include, or can operate by, logic or a number of components, or mechanisms. Circuit sets are a collection of circuits implemented in tangible entities that include hardware (e.g., simple circuits, gates, logic, etc.). Circuit set membership can be flexible over time and underlying hardware variability. Circuit sets include members that can, alone or in combination, perform specified operations when operating. In an example, hardware of the circuit set can be immutably designed to carry out a specific operation (e.g., hardwired). In an example, the hardware of the circuit set can include variably connected physical components (e.g., execution units, transistors, simple circuits, etc.) including a computer readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuit set in hardware via the variable connections to carry out portions of the specific operation when in operation. Accordingly, the computer readable medium is communicatively coupled to the other components of the circuit set member when the device is operating. In an example, any of the physical components can be used in more than one member of more than one circuit set. For example, under operation, execution units can be used in a first circuit of a first circuit set at one point in time and reused by a second circuit in the first circuit set, or by a third circuit in a second circuit set at a different time.

Machine 600 (e.g., computer system) can include a hardware processor 602 (e.g., a central processing unit (CPU), a graphics processing unit (GPU), a hardware processor core, field programmable gate array (FPGA), or any combination thereof), a main memory 604 and a static memory 606, some or all of which can communicate with each other via an interlink (e.g., bus) 630. The machine 600 can further include a display unit 610, an alphanumeric input device 612 (e.g., a keyboard), and a user interface (UI) navigation device 614 (e.g., a mouse). In an example, the display unit 610, input device 612 and UI navigation device 614 can be a touch screen display. The machine 600 can additionally include a storage device 608 (e.g., drive unit), a signal generation device 618 (e.g., a speaker), a network interface device 620 to connect the machine 600 to a network 626, and one or more sensors 616, such as a global positioning system (GPS) sensor, compass, accelerometer, or other sensor. The machine 600 can include an output controller 628, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 608 can include a machine readable medium 622 (e.g., a non-transitory medium) on which is stored one or more sets of data structures or instructions 624 (e.g., software) embodying or used by any one or more of the techniques or functions described herein. The instructions 624 can also reside, completely or at least partially, within the main memory 604, within static memory 606, or within the hardware processor 602 during execution thereof by the machine 600. In an example, one or any combination of the hardware processor 602, the main memory 604, the static memory 606, or the storage device 608 can constitute machine readable media.

While the machine readable medium 622 is illustrated as a single medium, the term “machine readable medium” can include a single medium or multiple media (e.g., a centralized or distributed database, and/or associated caches and servers) configured to store the one or more instructions 624. The term “machine readable medium” can include any non-transitory medium that is capable of storing, encoding, or carrying instructions for execution by the machine 600 and that cause the machine 600 to perform any one or more of the techniques of the present disclosure, or that is capable of storing, encoding, or carrying data structures used by or associated with such instructions. Non-limiting machine readable medium examples can include solid-state memories, and optical and magnetic media. In an example, a massed machine readable medium comprises a machine readable medium with a plurality of particles having invariant (e.g., rest) mass. Accordingly, massed machine-readable media are not transitory propagating signals. Specific examples of massed machine readable media can include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

### ADDITIONAL NOTES & EXAMPLES

Example 1 is a system for training a digital twin of a system-under-test, comprising: processing circuitry; and memory, with instructions stored thereon which, when performed by the processing circuitry cause the processing circuitry to: receive multiple inputs with information corresponding to the system-under-test; provide the multiple inputs as a data input to a large language model; configure an experiment with the large language model, based on the multiple inputs; configure a process flow for the experiment, using data output generated from the large language model; generate a training data set using the experiment and the process flow; and configure a digital twin of the system-under-test using the training data set.

In Example 2, the subject matter of Example 1 optionally includes subject matter wherein a first input of the multiple inputs includes a natural language description of the experiment, wherein a second input of the multiple inputs includes application programming interface documentation of the system-under-test, and wherein a third input of the multiple inputs includes one or more rules defining an input and an output for one or more actions used to configure the experiment.

In Example 3, the subject matter of Example 2 optionally includes subject matter wherein to configure the experiment includes to use the natural language description of the experiment to generate a plurality of augmented experiments in real-time, wherein the plurality of augmented experiments are permutations of the experiment determined from a natural language description of the experiment and a description of two or more modifications to be made to the experiment.

In Example 4, the subject matter of Example 3 optionally includes subject matter wherein the training data set is generated via a command that causes the processing circuitry to iterate through the plurality of augmented experiments using a set of generated prompts.

In Example 5, the subject matter of any one or more of Examples 3-4 optionally include subject matter wherein the training data set is generated, at least in part by translating the natural language description of the experiment to one or more application programming interface calls.

In Example 6, the subject matter of any one or more of Examples 3-5 optionally include subject matter wherein the training data set includes a stored input feature and a stored output feature.

In Example 7, the subject matter of Example 6 optionally includes subject matter wherein to configure the process flow includes to construct a dependency graph of the one or more actions, and wherein the instructions further cause the processing circuitry to: execute the one or more actions sequentially or in parallel to generate the stored output feature; and create a log, using the dependency graph, documenting the one or more actions, including a sequence in which the one or more actions were executed.

In Example 8, the subject matter of Example 7 optionally includes subject matter wherein the instructions cause the processing circuitry to: annotate the dependency graph with a partial order tag to each of the one or more actions, wherein the partial order tag defines an order for the one or more actions at least one of in time or as a delta-cycle.

Example 9 is a non-transitory machine-readable medium with instructions stored thereon which, when performed by a processor of a computing device cause the processor to: receive multiple inputs with information corresponding to a system-under-test; provide the multiple inputs as a data input to a large language model; configure an experiment with the large language model, based on the multiple inputs; configure a process flow for the experiment, using data output generated from the large language model; generate a training data set using the experiment and the process flow; and configure a digital twin of the system-under-test using the training data set.

In Example 10, the subject matter of Example 9 optionally includes subject matter wherein a first input of the multiple inputs includes a natural language description of the experiment, wherein a second input of the multiple inputs includes application programming interface documentation of the system-under-test, and wherein a third input of the multiple inputs includes one or more rules defining an input and an output for one or more actions used to configure the experiment.

In Example 11, the subject matter of Example 10 optionally includes subject matter wherein to configure the experiment includes to use the natural language description of the experiment to generate a plurality of augmented experiments in real-time, wherein the plurality of augmented experiments are permutations of the experiment determined from a natural language description of the experiment and a description of two or more modifications to be made to the experiment.

In Example 12, the subject matter of Example 11 optionally includes subject matter wherein the training data set is generated via a command that causes the processor to iterate through the plurality of augmented experiments using a set of generated prompts.

In Example 13, the subject matter of any one or more of Examples 11-12 optionally include subject matter wherein the training data set is generated, at least in part by translating the natural language description of the experiment to one or more application programming interface calls.

In Example 14, the subject matter of any one or more of Examples 10-13 optionally include subject matter wherein the training data set includes a stored input feature and a stored output feature.

In Example 15, the subject matter of Example 14 optionally includes subject matter wherein to configure the process flow includes to construct a dependency graph of the one or more actions, and wherein the instructions further cause the processor to: execute the one or more actions sequentially or in parallel to generate the stored output feature; and create a log documenting the one or more actions, including a sequence in which the one or more actions were executed.

In Example 16, the subject matter of Example 15 optionally includes subject matter wherein the instructions cause the processor to: annotate the dependency graph with a partial order tag to each of the one or more actions, wherein the partial order tag defines an order for the one or more actions at least one of in time or as a delta-cycle.

Example 17 is a system for creating a digital twin of a system-under-test, comprising: processing circuitry; and memory, with instructions stored thereon which, when performed by the processing circuitry cause the processing circuitry to: receive multiple inputs with information corresponding to the system-under-test; provide the multiple inputs as a data input to a large language model; configure an experiment with the large language model, based on the multiple inputs; configure a process flow for the experiment, using data output generated from the large language model, wherein to configure the process flow includes to construct a dependency graph of one or more actions; generate a training data set using the experiment and the process flow, wherein the training data set includes a stored input feature and a stored output feature; annotate the dependency graph with a partial order tag to each of the one or more actions; execute the one or more actions sequentially or in parallel to generate the stored output feature; create a log documenting the one or more actions, including a sequence in which the one or more actions were executed; and output a digital twin of the system-under-test using the training data set.

In Example 18, the subject matter of Example 17 optionally includes subject matter wherein a first input of the multiple inputs includes a natural language description of the experiment, wherein a second input of the multiple inputs includes application programming interface documentation of the system-under-test, and wherein a third input of the multiple inputs includes one or more rules defining an input and an output for one or more actions used to configure the experiment.

In Example 19, the subject matter of Example 18 optionally includes subject matter wherein to configure the experiment includes to use the natural language description of the experiment to generate a plurality of augmented experiments in real-time, wherein the plurality of augmented experiments are permutations of the experiment determined from a natural language description of the experiment and a description of two or more modifications to be made to the experiment, and wherein the training data set is generated, at least in part by translating the natural language description of the experiment to one or more application programming interface calls.

In Example 20, the subject matter of Example 19 optionally includes subject matter wherein the training data set is generated via a command that causes the processing circuitry to iterate through the plurality of augmented experiments using a set of generated prompts.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

The algorithms discussed herein may include an artificial intelligence (AI) or machine learning (ML) or other algorithm (e.g., a non-AI or non-ML deterministic algorithm) or process. Portions of the actions, methods, or operations discussed herein may be performed using a hardware-based feedback loop or feedback control. The hardware-based feedback loop or feedback control, the AI or ML algorithms, and the non-AI or non-ML algorithms may be used separately or in conjunction with each other as appropriate or desired.

As used herein, The term “processor” is synonymous with terms like “controller” and “computer” and should be understood to encompass not only computers having different architectures such as single/multi-processor architectures and sequential (Von Neumann)/parallel architectures but also specialized circuits such as field-programmable gate arrays (FPGA), application specific circuits (ASIC), signal processing devices and other devices.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the embodiments should be determined with reference to the appended claims, along with the full scope of equivalents to which such claims are entitled.

What is claimed is:

1. A system for training a digital twin of a system-under-test, comprising:
processing circuitry; and
memory, with instructions stored thereon which, when performed by the processing circuitry cause the processing circuitry to:
receive multiple inputs with information corresponding to the system-under-test;
provide the multiple inputs as a data input to a large language model;
configure an experiment with the large language model, based on the multiple inputs;
configure a process flow for the experiment, using data output generated from the large language model;
generate a training data set using the experiment and the process flow; and
configure a digital twin of the system-under-test using the training data set.

2. The system of claim 1, wherein a first input of the multiple inputs includes a natural language description of the experiment, wherein a second input of the multiple inputs includes application programming interface documentation of the system-under-test, and wherein a third input of the multiple inputs includes one or more rules defining an input and an output for one or more actions used to configure the experiment.

3. The system of claim 2, wherein to configure the experiment includes to use the natural language description of the experiment to generate a plurality of augmented experiments in real-time, wherein the plurality of augmented experiments are permutations of the experiment determined from a natural language description of the experiment and a description of two or more modifications to be made to the experiment.

4. The system of claim 3, wherein the training data set is generated via a command that causes the processing circuitry to iterate through the plurality of augmented experiments using a set of generated prompts.

5. The system of claim 3, wherein the training data set is generated, at least in part by translating the natural language description of the experiment to one or more application programming interface calls.

6. The system of claim 3, wherein the training data set includes a stored input feature and a stored output feature.

7. The system of claim 6, wherein to configure the process flow includes to construct a dependency graph of the one or more actions, and wherein the instructions further cause the processing circuitry to:
execute the one or more actions sequentially or in parallel to generate the stored output feature; and
create a log, using the dependency graph, documenting the one or more actions, including a sequence in which the one or more actions were executed.

8. The system of claim 7, wherein the instructions cause the processing circuitry to:
annotate the dependency graph with a partial order tag to each of the one or more actions, wherein the partial order tag defines an order for the one or more actions at least one of in time or as a delta-cycle.

9. A non-transitory machine-readable medium with instructions stored thereon which, when performed by a processor of a computing device cause the processor to:
receive multiple inputs with information corresponding to a system-under-test;
provide the multiple inputs as a data input to a large language model;
configure an experiment with the large language model, based on the multiple inputs;
configure a process flow for the experiment, using data output generated from the large language model;
generate a training data set using the experiment and the process flow; and
configure a digital twin of the system-under-test using the training data set.

10. The non-transitory machine-readable medium of claim 9, wherein a first input of the multiple inputs includes a natural language description of the experiment, wherein a second input of the multiple inputs includes application programming interface documentation of the system-under-test, and wherein a third input of the multiple inputs includes one or more rules defining an input and an output for one or more actions used to configure the experiment.

11. The non-transitory machine-readable medium of claim 10, wherein to configure the experiment includes to use the natural language description of the experiment to generate a plurality of augmented experiments in real-time, wherein the plurality of augmented experiments are permutations of the experiment determined from a natural language description of the experiment and a description of two or more modifications to be made to the experiment.

12. The non-transitory machine-readable medium of claim 11, wherein the training data set is generated via a command that causes the processor to iterate through the plurality of augmented experiments using a set of generated prompts.

13. The non-transitory machine-readable medium of claim 11, wherein the training data set is generated, at least in part by translating the natural language description of the experiment to one or more application programming interface calls.

14. The non-transitory machine-readable medium of claim 10, wherein the training data set includes a stored input feature and a stored output feature.

15. The non-transitory machine-readable medium of claim 14, wherein to configure the process flow includes to construct a dependency graph of the one or more actions, and wherein the instructions further cause the processor to:
execute the one or more actions sequentially or in parallel to generate the stored output feature; and
create a log documenting the one or more actions, including a sequence in which the one or more actions were executed.

16. The non-transitory machine-readable medium of claim 15, wherein the instructions cause the processor to:
annotate the dependency graph with a partial order tag to each of the one or more actions, wherein the partial order tag defines an order for the one or more actions at least one of in time or as a delta-cycle.

17. A system for creating a digital twin of a system-under-test, comprising:
processing circuitry; and
memory, with instructions stored thereon which, when performed by the processing circuitry cause the processing circuitry to:
receive multiple inputs with information corresponding to the system-under-test;
provide the multiple inputs as a data input to a large language model;
configure an experiment with the large language model, based on the multiple inputs;
configure a process flow for the experiment, using data output generated from the large language model, wherein to configure the process flow includes to construct a dependency graph of one or more actions;
generate a training data set using the experiment and the process flow, wherein the training data set includes a stored input feature and a stored output feature;
annotate the dependency graph with a partial order tag to each of the one or more actions;
execute the one or more actions sequentially or in parallel to generate the stored output feature;
create a log documenting the one or more actions, including a sequence in which the one or more actions were executed; and
output a digital twin of the system-under-test using the training data set.

18. The system of claim 17, wherein a first input of the multiple inputs includes a natural language description of the experiment, wherein a second input of the multiple inputs includes application programming interface documentation of the system-under-test, and wherein a third input of the multiple inputs includes one or more rules defining an input and an output for one or more actions used to configure the experiment.

19. The system of claim 18, wherein to configure the experiment includes to use the natural language description of the experiment to generate a plurality of augmented experiments in real-time, wherein the plurality of augmented experiments are permutations of the experiment determined from a natural language description of the experiment and a description of two or more modifications to be made to the experiment, and wherein the training data set is generated, at least in part by translating the natural language description of the experiment to one or more application programming interface calls.

20. The system of claim 19, wherein the training data set is generated via a command that causes the processing circuitry to iterate through the plurality of augmented experiments using a set of generated prompts.
